(19) United States
(12) Patent Application Publication
(10) Pub. No.: US 2007/0004092 A1
(43) Pub. Date: Jan. 4, 2007

(54) Semiconductor device manufacturing method

(76) Inventors: Hiromichi Suzuki, TOKYO (JP); Fujio Ito, Hanno (JP); Toshio Sasaki, Mizuho (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/569,735

(22) PCT Filed: Aug. 29, 2003
(86) PCT No.: PCT/JP03/11121

§ 371 Date: Feb. 28, 2006

(51) Int. Cl. H01L 21/00

(52) U.S. Cl. 438/123

(57) ABSTRACT

This manufacturing method of a semiconductor device prepares a lead frame to which a heat spreader, and the tip parts of a plurality of inner leads were joined via a thermoplastic insulating binding material, arranges a lead frame on a heat stage, and joins the semiconductor chip to the heat spreader via the thermoplastic binding material which was heated and softened after having arranged the semiconductor chip on the heat spreader. Die bonding can be performed without scattering inner leads by joining the semiconductor chip and the thermoplastic binding material, suppressing the tip parts of the inner leads to the heat stage side. Improvement in the assembling property of a semiconductor device can be aimed at.

The present application claims priority from PCT application PCT/JP03/011121 filed on Aug. 29, 2003, the content of which is hereby incorporated by reference into this application.

### TECHNICAL FIELD

The present invention relates to a manufacturing method of a semiconductor device, and particularly relates to the manufacturing method of the semiconductor device with a bar lead of ring shape.

### BACKGROUND ART

The semiconductor device of the structure which stuck the heat spreader (sheet member) on the tip part of an inner lead via the insulating binding material is known as a semiconductor device which increased heat radiation property, and the semiconductor chip is mounted on the central part on the heat spreader.

In the semiconductor device, there is a thing of structure which has a bar lead (it is also called a bus bar) as a common lead, for example, when a bar lead is frame shape (square ring shape), a bar lead is arranged to the region between the semiconductor chip, and the tip group of inner leads.

About such a semiconductor device, PCT/JP03/06151 has the description.

The present inventor considered the assembly of the semiconductor device. As a result, it was found out that a wire short circuit by the flow pressure of the resin for sealing is caused, and that we are anxious about it is difficult for the resin for sealing to go around to a chip back surface, etc. in the case where small tab (tab is smaller than chip back surface) structure is adopted, at the time of resin molding.

Although the lead frame in which inner leads, and the connection part which connects the tips were attached to a heat spreader via an adhesives layer, and its manufacturing method are described in Japanese Unexamined Patent Publication No. Hei 9-252072, there is no description about the concrete manufacturing method of the semiconductor device using the lead frame.

The purpose of the present invention is to offer the manufacturing method of the semiconductor device which aims at improvement in assembling property.

The other purpose of the present invention is to offer the manufacturing method of the semiconductor device which aims at improvement in the reliability of a product.

The above-described and the other purposes and novel features of the present invention will become apparent from the description herein and accompanying drawings.

### DISCLOSURE OF THE INVENTION

The present invention comprises the steps of: preparing a lead frame in which a sheet member, and tip parts of a plurality of inner leads were joined via a thermoplastic insulating binding material; arranging the lead frame over a stage; and arranging a semiconductor chip over the sheet member of the lead frame, and joining the semiconductor chip to the sheet member via the thermoplastic binding material which was heated and softened; wherein the semiconductor chip and the thermoplastic binding material are joined, suppressing the tip parts of the inner leads to the stage side.

### BRIEF DESCRIPTION OF THE DRAWINGS

FIG. 1 is a sectional view showing an example of the structure of the semiconductor device of Embodiment 1 of the present invention,

FIG. 2 is a sectional view showing an example of the structure of a lead frame used for the assembly of the semiconductor device shown in FIG. 1,

FIG. 3 is a sectional view showing an example of a chip transfer condition at the time of die bonding in the assembly of the semiconductor device shown in FIG. 1,

FIG. 4 is a sectional view showing an example of a chip sticking-by-pressure condition at the time of die bonding in the assembly of the semiconductor device shown in FIG. 1,

FIG. 5 is a sectional view showing an example of the condition after die bonding in the assembly of the semiconductor device shown in FIG. 1,

FIG. 6 is a sectional view showing an example of the condition after the wire bonding in the assembly of the semiconductor device shown in FIG. 1,

FIG. 7 is a sectional view showing an example of the metal-mold clamp state at the time of resin molding of the assembly of the semiconductor device shown in FIG. 1,

FIG. 8 is a sectional view showing an example of a resin injection condition at the time of resin molding of the assembly of the semiconductor device shown in FIG. 1,

FIG. 9 is a sectional view showing an example of the structure after the termination of resin molding in the assembly of the semiconductor device shown in FIG. 1,

FIG. 10 is a sectional view showing an example of the structure of the semiconductor device of Embodiment 2 of the present invention,

FIG. 11 is a plan view showing an example of the structure of a lead frame used for the assembly of the semiconductor device shown in FIG. 10,

FIG. 12 is a sectional view showing an example of the condition after die bonding in the assembly of the semiconductor device shown in FIG. 10,

FIG. 13 is a sectional view showing an example of the condition after the wire bonding in the assembly of the semiconductor device shown in FIG. 10,

FIG. 14 is a sectional view showing an example of the metal-mold clamp state at the time of resin molding of the assembly of the semiconductor device shown in FIG. 10,

FIG. 15 is a sectional view showing an example of a resin injection condition at the time of resin molding of the assembly of the semiconductor device shown in FIG. 10,

FIG. 16 is a sectional view showing an example of the structure after the termination of resin molding in the assembly of the semiconductor device shown in FIG. 10,

FIG. 17 is a plan view showing an example of a wiring condition in the assembly of the semiconductor device of Embodiment 3 of the present invention, and

FIG. 18 is a plan view showing an example of a wiring condition in the assembly of the semiconductor device of Embodiment 4 of the present invention.

### BEST MODE FOR CARRYING OUT THE INVENTION

Hereafter, embodiments of the invention are explained in detail based on drawings.

In the below-described embodiments, a description will be made after divided in plural sections or in plural embodiments if necessary for convenience's sake. These plural sections or embodiments are not independent each other, but in a relation such that one is a modification example, details or complementary description of a part or whole of the other one unless otherwise specifically indicated.

And, in the below-described embodiments, when a reference is made to the number of elements (including the number, value, amount and range), the number is not limited to a specific number but can be greater than or less than the specific number unless otherwise specifically indicated or principally apparent that the number is limited to the specific number.

Moreover, in the below-described embodiments, it is needless to say that the constituting elements (including element steps) are not always essential unless otherwise specifically indicated or principally apparent that they are essential.

Similarly, in the below-described embodiments, when a reference is made to the shape or positional relationship of the constituting elements, that substantially analogous or similar to it is also embraced unless otherwise specifically indicated or principally apparent that it is not. This also applies to the above-described value and range.

And, in all the drawings for describing the embodiments, members of a like function will be identified by like reference numerals and overlapping descriptions will be omitted.

### Embodiment 1

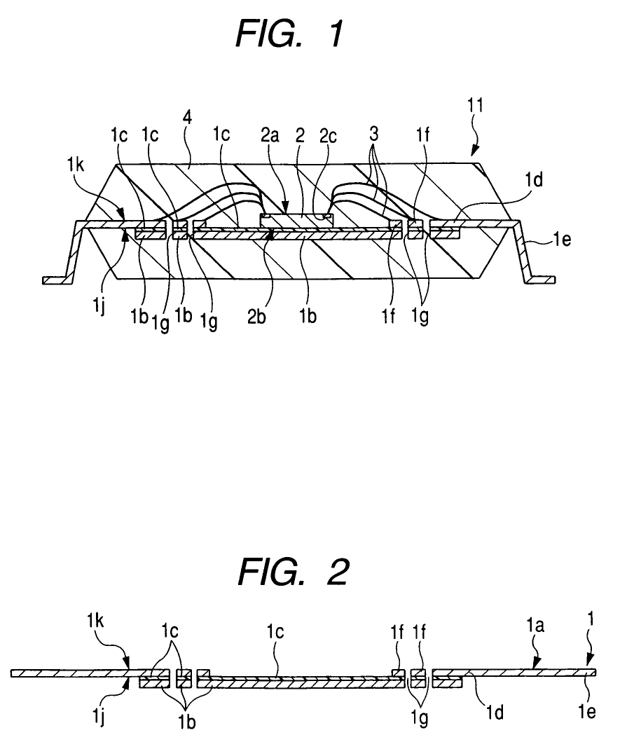

The semiconductor device of Embodiment 1 shown in FIG. 1 is a semiconductor package of a resin molded type with high heat radiation property, and QFP (Quad Flat Package) 11 by which bending forming of the outer leads 1e were performed at the shape of a gull wing is taken up and explained here.

The structure of QFP 11 is explained. A plurality of inner leads 1d, a plurality of outer leads 1e formed in one with this inner lead 1d, heat spreader 1b which is a sheet member joined to tip parts of a plurality of inner leads 1d via thermoplastic insulating binding material 1c, bar lead if which is a common lead of the square ring shape arranged at the inside of a plurality of inner leads, semiconductor chip 2 joined via thermoplastic binding material 1c on heat spreader 1b at the inside of bar lead if of ring shape, a plurality of electrically conductive wires 3, such as a gold wire which connect pad (electrode) 2c of semiconductor chip 2 and inner lead 1d corresponding to this, and pad 2c and bar lead if, and sealing body 4 which seals semiconductor chip 2 and a plurality of wires 3 with resin are included.

Namely, in QFP 11, the tip parts of inner leads 1d, bar lead if of ring shape, and semiconductor chip 2 have joined to heat spreader 1b via thermoplastic insulating binding material 1c, respectively. Thermoplastic binding material 1c is a binding material whose glass transition temperature is more than or equal to the heating temperature at the time of wire bonding (for example, about 230° C.), desirably 250° C. or more.

That is, the temperature at which thermoplastic binding material 1c softens is more than or equal to the heating temperature at the time of wire bonding, desirably more than or equal to 250° C.

Hereby, it can prevent thermoplastic binding material's 1c becoming soft, and inner lead 1d moving on thermoplastic binding material 1c, or peeling from thermoplastic binding material 1c at the time of the wire bonding in the assembly of QFP 11.

Wire 3 of power supply potential or GND potential is connected to bar lead 1f of the ring shape which is a common lead.

Next, the manufacturing method of QFP 11 of Embodiment 1 is explained.

First, lead frame 1 shown in the FIG. 2 which has laminated metal frame body 1a provided with a plurality of inner leads 1d, a plurality of outer leads 1e formed in one with each of a plurality of inner leads 1d and bar lead if of the square ring shape arranged at the inside of a plurality of inner leads 1d, and has heat spreader 1b joined to this frame body 1a via thermoplastic insulating binding material 1c, is prepared.

In lead frame 1, the tip part of each inner lead 1d and bar lead if, and quadrangular heat spreader 1b are joined via thermoplastic binding material 1c, respectively.

That is, heat spreader 1b is a sheet shaped thing corresponding to an inner lead 1d row, and it has a chip mounting function while it is a quadrangle.

In lead frame 1, punching holes (first through holes) 1g formed by lead trimming are formed at the outside of each bar lead 1f of square ring shape. Punching holes 1g formed between the inner lead 1d group and bar lead 1f among punching holes 1g adjoin a tip part of an each inner lead 1d, and are formed along the column direction of inner lead 1d. Therefore, between a plurality of inner leads 1d and square bar lead 1f which adjoined this, four long and slender punching holes 1g are formed (refer to FIG. 11).

Then, die bonding is performed.

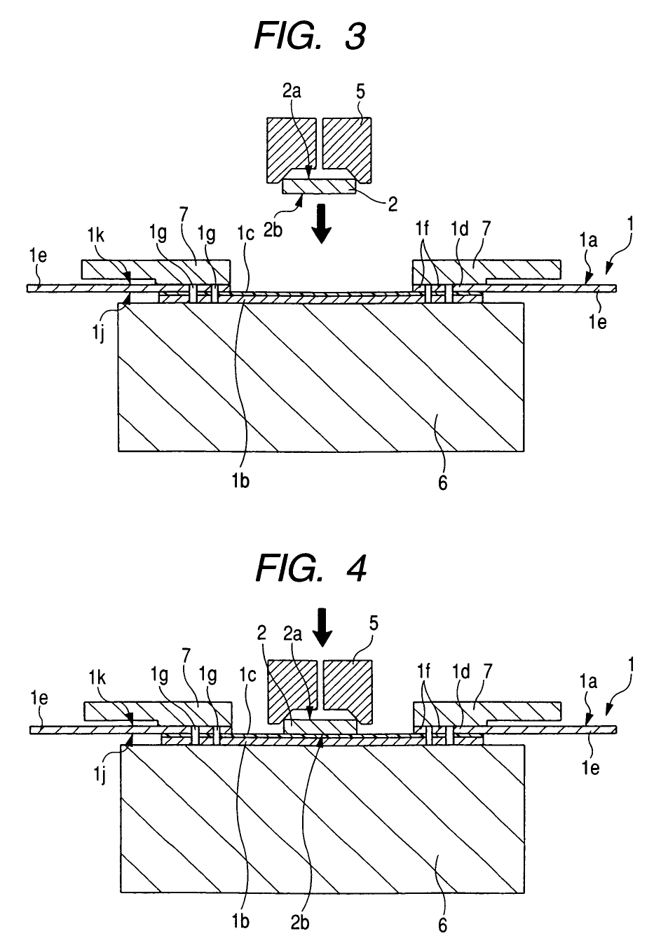

First, as shown in FIG. 3, lead frame 1 is arranged on heat stage 6 (stage). Heat stage 6 is beforehand heated to predetermined temperature (for example, more than or equal to 300° C.) in that case. Hereby, heat is transmitted from heat stage 6 to thermoplastic binding material 1c via heat spreader 1b after lead frame arrangement on heat stage 6, and when prescribed temperature is reached, thermoplastic binding material 1c will begin to become soft.

Then, by performing an adsorption hold of the main surface 2a side of semiconductor chip 2 and transferring with collet 5, semiconductor chip 2 is arranged above the chip mounting region of heat spreader 1b of lead frame 1.

Then, as shown in FIG. 4, with collet 5, where the adsorption hold of the semiconductor chip 2 is performed, collet 5 is dropped, and back surface 2b of semiconductor chip 2 is joined to thermoplastic binding material 1c on heat spreader 1b.

Semiconductor chip 2 is joined to thermoplastic binding material 1c on heat spreader 1b via thermoplastic binding material 1c which was heated and softened in the condition of having pressed down the tip parts of a plurality of inner leads 1d and bar lead 1f to the heat stage 6 side with jig 7, in that case.

Although thermoplastic binding material 1c is softened at this time, since each inner lead 1d and bar lead 1f are suppressed by retaining jig 7 to the heat stage 6 side, die bonding can be performed without making inner lead 1d scattered without inner lead 1d peeling from thermoplastic binding material 1c, or moving on thermoplastic binding material 1c.

Only thermoplastic binding material 1c can perform die bonding, without using special die bond material.

As a result, the step which applies die bond material can be skipped and improvement in the assembling property of a semiconductor device (QFP 11) can be aimed at.

Since special die bond material is not used, the manufacturing cost of a semiconductor device (QFP 11) can be reduced.

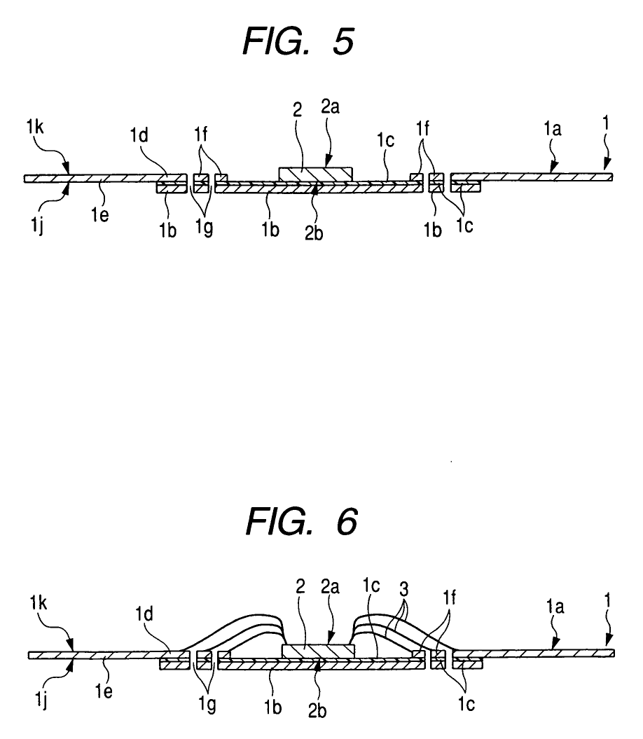

This becomes die-bonding completion, as shown in FIG. 5.

Then, wire bonding is performed as shown in FIG. 6.

That is, pad 2c (refer to FIG. 1) of semiconductor chip 2, and inner lead 1d corresponding to this and bar lead 1f are electrically connected with electrically conductive wire 3, respectively.

Then, resin molding is performed.

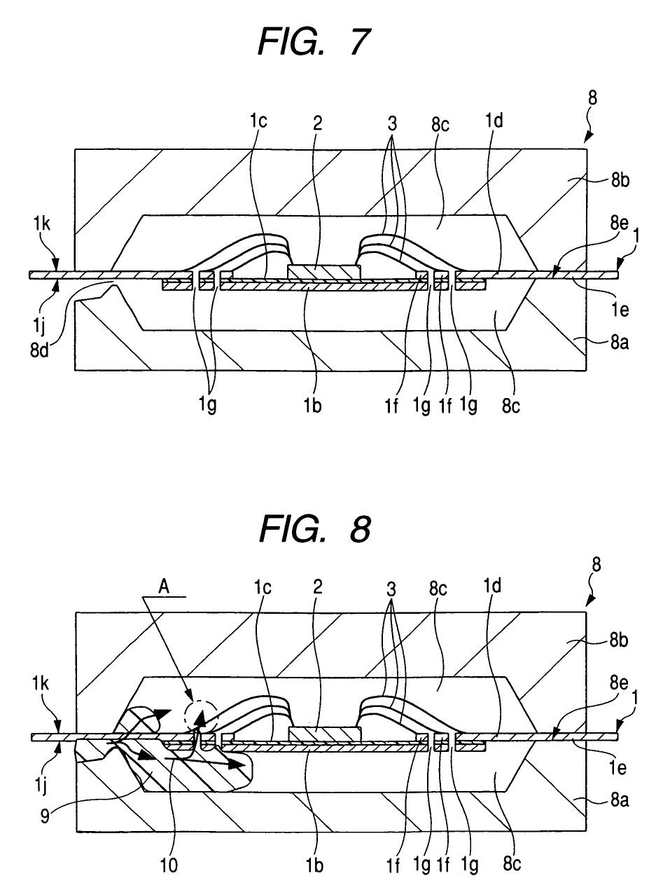

First, as shown in FIG. 7, forming mold 8 which includes a pair with first metal mold 8a (lower die) and second metal mold 8b (upper die) is prepared. The surface of the side on which semiconductor chip 2 is not mounted, i.e., back surface 1j of lead frame 1 is arranged on metal-mold surface 8e of first metal mold 8a with which gate 8d was formed among forming mold 8, and first metal mold 8a and second metal mold 8b are clamped after that.

This will become the condition that a plurality of inner leads 1d, semiconductor chip 2, a plurality of wires 3, and heat spreader 1b were covered with cavity 8c of forming mold 8.

Then, as shown in FIG. 8, resin 9 for sealing is poured in into cavity 8c of forming mold 8 from gate 8d (refer to FIG. 7) of first metal mold 8a arranged at the back surface 1j side of lead frame 1. By this, as for resin 9 for sealing poured in into cavity 8c, while flowing along the back surface 1j side of lead frame 1 so that heat spreader 1b may be covered, and filling up cavity 8c at the side of back surface 1j, it flows also into cavity 8c at the side of front surface 1k via opening of gate contiguity of lead frame 1, and cavity 8c at the side of front surface 1k is also filled up.

In the process in which resin 9 for sealing poured into the back surface 1j side flows by flow 10 of resin, it flows into the front surface 1k side through punching holes 1g formed between inner lead 1d and bar lead 1f by injection pressure, and as shown in the A section of FIG. 8, wire 3 connected to inner lead 1d arranged at the front surface 1k side is pushed up.

Namely, since it flows into the front surface 1k side so that resin 9 for sealing may arise through punching holes 1g between inner lead 1d and bar lead 1f from the back surface 1j side of lead frame 1 by arranging gate 8d at the back surface 1j side of lead frame 1, wire 3 can be pushed up and a tension can be given to wire 3.

Hereby, it becomes difficult to generate a wire short circuit and wire deformation, and improvement in the reliability of a product can be aimed at.

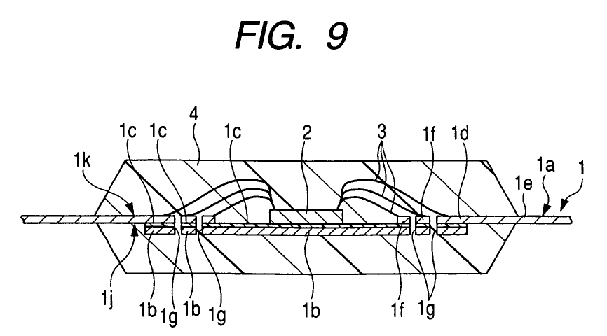

Thus, cavity 8c of back-and-front both sides is filled up with resin 9 for sealing, and sealing body 4 which becomes completion of resin molding shown in FIG. 9 is formed.

Then, cut formation of outer leads 1e is performed, and it becomes assembly completion of QFP 11 shown in FIG. 1.

### Embodiment 2

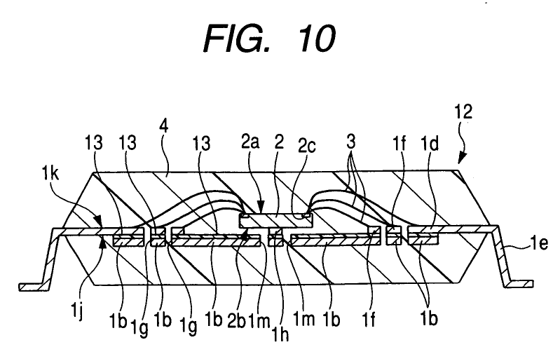

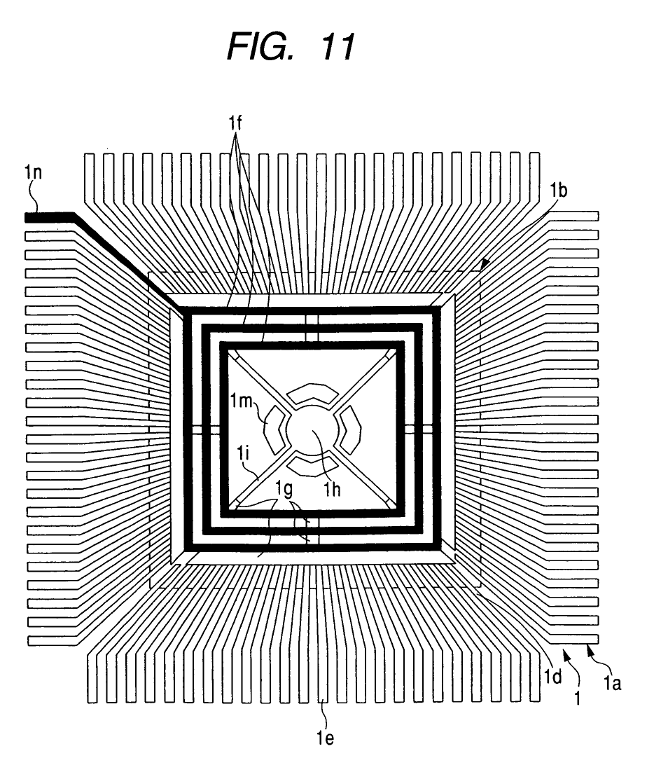

Like QFP 11 of Embodiment 1, the semiconductor device of Embodiment 2 shown in FIG. 10 is QFP 12 of a resin molded type with heat spreader (sheet member) 1b, in order to increase heat radiation property. A different point from QFP 11 of Embodiment 1 is that tab 1h which is a far small chip mounting part is formed via insulating adhesion member 13 (binding material) on heat spreader 1b as compared with back surface 2b of semiconductor chip 2.

That is, QFP 12 of Embodiment 2 is a semiconductor device of small tab structure.

The structure of QFP 12 is explained, a plurality of inner leads 1d and a plurality of outer leads 1e formed in one with this inner lead 1d, heat spreader 1b joined to tip parts of a plurality of inner leads 1d via insulating adhesion member 13, bar lead if of the square ring shape arranged at the inside of a plurality of inner leads 1d, tab 1h which is a chip mounting part far smaller than back surface 2b of semiconductor chip 2, and is fixed via insulating adhesion member 13 on heat spreader 1b at the inside of bar lead if of ring shape, semiconductor chip 2 mounted on this tab 1h, a plurality of electrically conductive wires 3 which connect pad (electrode) 2c of semiconductor chip 2 and inner lead 1d corresponding to this, and pad 2c and bar lead if, such as gold wires, and sealing body 4 which seals semiconductor chip 2 and a plurality of wires 3 with resin are included.

That is, QFP 12 shown in FIG. 10 is the thing of a small tab structure by which semiconductor chip 2 was mounted on small tab 1h formed via insulating adhesion member 13 on heat spreader 1b.

Tab 1h is connected with four suspension leads 1i as shown in FIG. 11, and suspension lead 1i is insulated with bar lead if of ring shape by punching holes 1g. However, suspension lead 1i and bar lead 1f of the maximum inside may be connected.

A through hole 1m which is a second through hole formed in heat spreader 1b is formed in the perimeter of tab 1h.

This through hole 1m is a hole for fully circulating resin 9 for sealing in the gap of back surface 2b of semiconductor chip 2, and heat spreader 1b at the time of resin molding. By fully filling up the gap of back surface 2b of semiconductor chip 2, and heat spreader 1b with resin 9 for sealing, a chip back surface and resin 9 for sealing can adhere, and improvement in reflow crack resistance can be aimed at.

As long as adhesion member 13 adopted by Embodiment 2 is an insulating thing, it may be a thermoplastic binding material and may be binding materials other than thermoplasticity.

Since it is the same as that of QFP 11 of Embodiment 1 about the other structures of QFP 12 of Embodiment 2, the explanation is omitted.

Next, the manufacturing method of QFP 12 of Embodiment 2 is explained.

First, lead frame 1 shown in FIG. 11 is prepared.

Namely, lead frame 1 with a plurality of inner leads 1d, a plurality of outer leads 1e formed in one with this inner lead 1d, heat spreader 1b which is joined to tip parts of a plurality of inner leads 1d via insulating adhesion member 13 and which is a laminated sheet member, bar lead 1f of the square ring shape arranged at the inside of a plurality of inner leads 1d, tab 1h fixed via insulating adhesion member 13 on heat spreader 1b at the inside of bar lead 1f of ring shape, and suspension lead 1i connected with tab 1h, is prepared.

In lead frame 1, a tip part of each inner lead 1d, bar lead 1f and tab 1h, and quadrangular heat spreader 1b are joined via insulating adhesion member (binding material) 13, respectively. Heat spreader 1b is a sheet shaped thing corresponding to an inner lead 1d row, and it has a chip mounting function while it is a quadrangle.

In lead frame 1, punching holes 1g (first through holes) formed by lead trimming are formed at the outside of each bar lead if of square ring shape. Punching holes 1g formed between the inner lead 1d group and bar lead if among punching holes 1g adjoin a tip part of an each inner lead 1d, and are formed along the column direction of the inner leads 1d. Therefore, between a plurality of inner leads 1d and square bar lead 1f which adjoined this, four long and slender punching holes 1g are formed (refer to FIG. 11).

As compared with back surface 2b of semiconductor chip 2 mounted, the size of tab 1h is far small, and a plurality of through holes (second through holes) 1m are further formed in the perimeter of tab 1h.

Then, die bonding is performed.

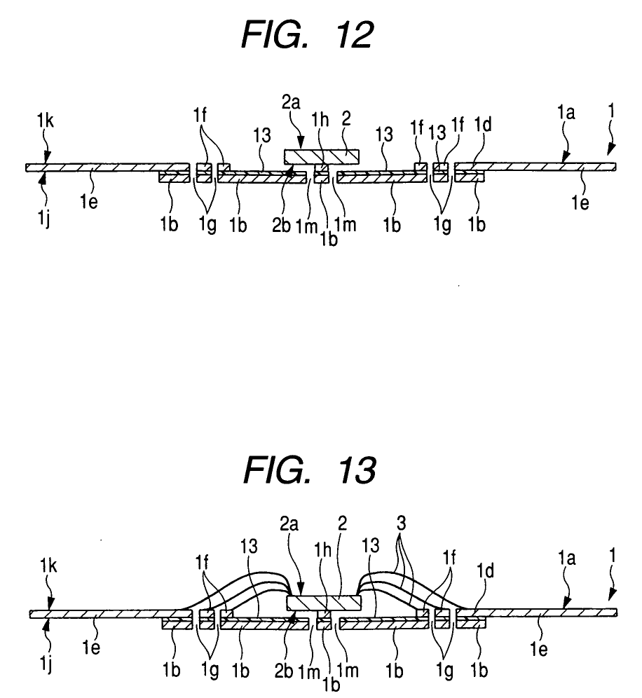

Here, semiconductor chip 2 is mounted on tab 1h stuck over heat spreader 1b. That is, as shown in FIG. 12, the peripheral part of semiconductor chip 2 is protruded out from tab 1h to the perimeter, and is mounted on tab 1h. Semiconductor chip 2 is fixed to tab 1h by thermo compression bonding etc. in that case.

Then, wire bonding is performed as shown in FIG. 13.

That is, pad 2c (refer to FIG. 10) of semiconductor chip 2, and inner lead 1d corresponding to this and bar lead if are electrically connected with electrically conductive wire 3, respectively.

Then, resin molding is performed.

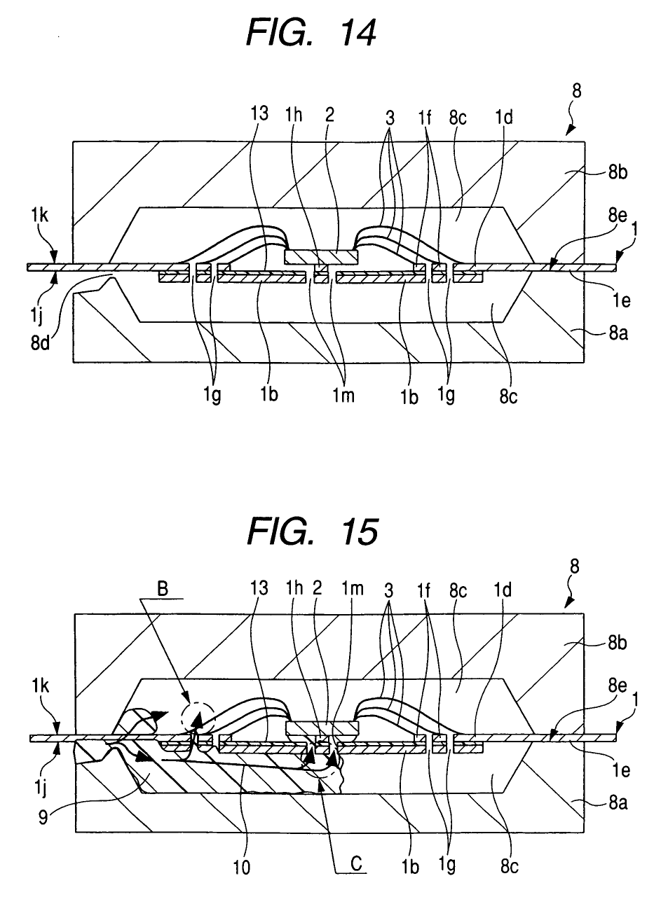

First, as shown in FIG. 14, forming mold 8 which includes a pair with first metal mold 8a (lower die) and second metal mold 8b (upper die) is prepared. The surface of the side on which semiconductor chip 2 is not mounted 1j, i.e., back surface, of lead frame 1 is arranged on metal-mold surface 8e of first metal mold 8a with which gate 8d was formed among forming mold 8, and first metal mold 8a and second metal mold 8b are clamped after that.

This will become the condition that a plurality of inner leads 1d, semiconductor chip 2, a plurality of wires 3, and heat spreader 1b were covered with cavity 8c of forming mold 8.

Then, as shown in FIG. 15, resin 9 for sealing is poured in into cavity 8c of forming mold 8 from gate 8d of first metal mold 8a arranged at the back surface 1j side of lead frame 1. By this, as for resin 9 for sealing poured in into cavity 8c, while it flows along the back surface 1j side of lead frame 1 so that heat spreader 1b may be covered, and fills up cavity 8c at the side of back surface 1j, it flows also into cavity 8c at the side of front surface 1k via opening of gate contiguity of lead frame 1, and cavity 8c at the side of front surface 1k is also filled up.

In the process in which resin 9 for sealing poured into the back surface 1j side flows by flow 10 of resin, by injection pressure, it flows into the front surface 1k side through punching holes 1g formed between inner lead 1d and bar lead if, and wire 3 connected to inner lead 1d arranged at the front surface 1k side as shown in the B section of FIG. 15 is pushed up.

Namely, since it flows into the front surface 1k side so that resin 9 for sealing may arise through punching holes 1g between inner lead 1d and bar lead if from the back surface 1j side of lead frame 1 by arranging gate 8d at the back surface 1j side of lead frame 1, wire 3 can be pushed up and tension can be given to wire 3.

Hereby, it becomes difficult to generate a wire short circuit and wire deformation, and improvement in the reliability of a product can be aimed at.

As for lead frame 1 of Embodiment 2, since a plurality of through holes 1m are formed in the perimeter of tab 1h, in near the back surface of semiconductor chip 2, as shown in the C section of FIG. 15, by injection pressure, resin 9 for sealing arranged at the back surface 1j side of lead frame 1 flows into the front surface 1k side through through holes 1m, and enters between back surface 2b of semiconductor chip 2, and adhesion member 13.

Hereby, resin 9 for sealing fully fills up also between back surface 2b of semiconductor chip 2, and heat spreader 1b.

As a result, a chip back surface and resin 9 for sealing adhere, it becomes hard for void to be formed, and reflow crack resistance can be increased. Therefore, improvement in the reliability of a product can be aimed at.

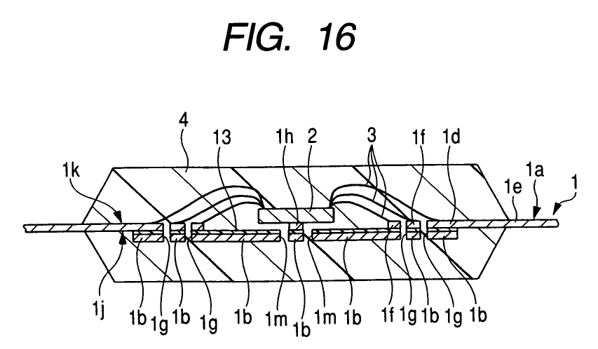

Thus, cavity 8c of back-and-front both sides is filled up with resin 9 for sealing, and sealing body 4 which becomes completion of resin molding shown in FIG. 16 is formed.

Then, cut formation of outer lead 1e is performed, and it becomes assembly completion of QFP 12 of the small tab structure shown in FIG. 10.

### Embodiment 3

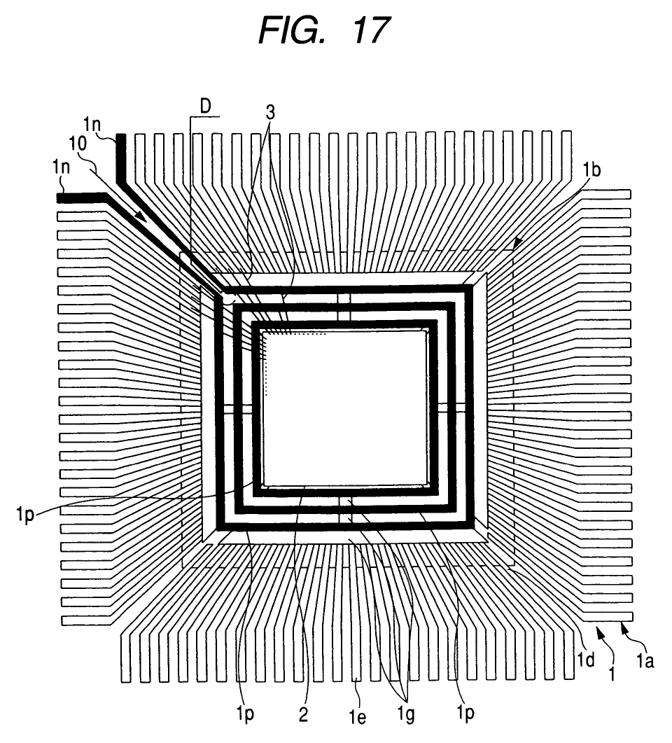

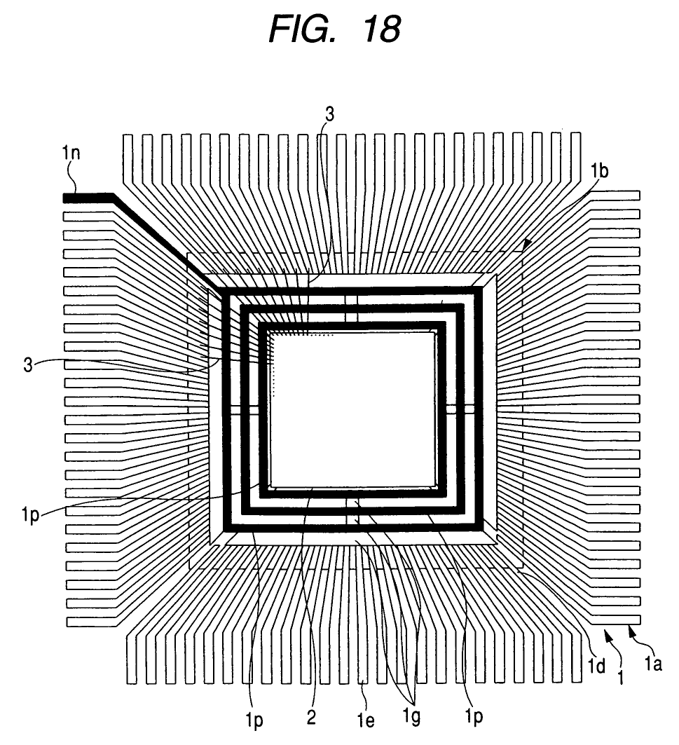

FIG. 17 shows a wiring condition in the assembly of the semiconductor device of Embodiment 3.

Lead frame 1 shown in FIG. 17 has a plurality of inner leads 1d, a plurality of outer leads 1e formed in one with this, heat spreader 1b which is a sheet member joined to tip parts of a plurality of inner leads 1d, frame shape lead 1p arranged inside four inner lead groups, and lead-out lead in connected with the corner part of this frame shape lead 1p. Heat spreader 1b and the tip parts of a plurality of inner leads, and heat spreader 1b and frame shape lead 1p are joined via adhesion member 13 (refer to FIG. 12).

That is, lead-out leads in which connected with frame shape lead 1p, and were pulled out outside are gathered and connected with the corner part of frame shape lead 1p.

By this, by wire bonding, pad 2c (refer to FIG. 10) of semiconductor chip 2, and inner lead 1d corresponding to this, furthermore, pad 2c of semiconductor chip 2, and the part which avoided near the corner part of frame shape lead 1p are electrically connected by wire 3, respectively.

In resin molding, resin molding is performed using forming mold 8 with which gate 8d (refer to FIG. 15), and lead-out lead in were formed in the corner part of the same location in this condition. That is, when gate 8d is formed in the corner part of cavity 8c, lead-out leads in connected with frame shape lead 1p are also brought together in the corner part of the same location, and are arranged.

Hereby, when resin 9 for sealing is poured in into cavity 8c from gate 8d, after becoming flow 10 of resin and flowing along lead-out leads in, it will diffuse and fill up with resin 9 for sealing in cavity 8c. Since wire 3 is not connected near the corner part of frame shape lead 1p in that case as shown in the D section of FIG. 17, interference with wire 3 near the corner part of poured-in resin 9 for sealing is avoidable. As a result, the generation of wire deformation can be prevented. Furthermore, formation of void can be reduced.

Therefore, improvement in the reliability of a product can be aimed at.

Also in the viewpoint of the length of wire 3, since wire 3 is not connected near the corner part of frame shape lead 1p at which the distance easily becomes distant from each pad 2c of semiconductor chip 2, wire 3 can be shortened generally.

### Embodiment 4

FIG. 18 shows a wiring condition in the assembly of the semiconductor device of Embodiment 4.

Lead frame 1 shown in FIG. 18 has a plurality of inner leads 1d, a plurality of outer leads 1e formed in one with this, heat spreader 1b which is a sheet member joined to the tip parts of a plurality of inner leads 1d, and frame shape lead 1p arranged inside four inner lead groups. Heat spreader 1b and the tip parts of a plurality of inner leads, and heat spreader 1b and frame shape lead 1p are joined via adhesion member 13 (refer to FIG. 12).

In the wire bonding of Embodiment 4, pad 2c (refer to FIG. 10) of semiconductor chip 2 and inner lead 1d corresponding to this are connected by wire 3, and as shown in FIG. 18, wire 3 is not connected to frame shape lead 1p.

That is, in Embodiment 4, frame shape lead 1p is formed not as a common lead but as an object for reinforcement of a sheet member. For example, when a sheet member is an insulating tape member etc., heat deformation of the tape member can be prevented by joining frame shape lead 1p and the tape member.

In that case, as shown in FIG. 18, the strength of the tape member can be further raised by forming frame shape lead 1p side by side at plural lines (Embodiment 4 three rows).

In resin molding, when resin 9 for sealing is injected into cavity 8c (refer to FIG. 15), with frame shape lead 1p, the inflow at the side of inner lead 1d of resin 9 for sealing is prevented, and cavity 8c is filled up with resin 9 for sealing.

That is, frame shape lead 1p serves as a dam, and the inflow to the side of a tip part of inner lead 1d of resin 9 for sealing can be prevented. As a result, improvement in the reliability of a product can be aimed at.

As things mentioned above, the present inventions accomplished by the present inventors were concretely explained based on above embodiments, but the present inventions are not limited by above embodiments, but variations and modifications may be made, of course, in various ways in the limit that does not deviate from the gist.

Although Embodiment 1-4 explained the case where a sheet member was heat spreader 1b, the sheet member may be a tape member or a substrate of a thin film etc.

Although Embodiment 1-4 took up and explained the case where a semiconductor device was QFP to the example, as long as the semiconductor device is a semiconductor device assembled using the lead frame by which the sheet member was stuck on the tip part of each inner lead 1d, they may be another semiconductor devices other than QFP.

### INDUSTRIAL APPLICABILITY

As mentioned above, the manufacturing method of the semiconductor device of the present invention is suitable for the manufacturing method of the semiconductor device which has a bar lead (frame shape lead), and especially suitable for the manufacturing method of the semiconductor device with which the outer leads have been arranged in the four directions.

1. A manufacturing method of a semiconductor device assembled using a lead frame which has a plurality of inner leads, a plurality of outer leads formed in one with this, and a sheet member joined to tip parts of the inner leads, comprising the steps of:
(a) preparing the lead frame in which the sheet member, and the tip parts of the inner leads were joined via a thermoplastic insulating binding material;
(b) arranging the lead frame over a stage; and
(c) arranging a semiconductor chip over the sheet member of the lead frame, and joining the semiconductor chip to the sheet member via the thermoplastic binding material which was heated and softened;
wherein in the step (c), the semiconductor chip and the thermoplastic binding material are joined, suppressing the tip parts of the inner leads to the stage side.

2. A manufacturing method of a semiconductor device according to claim 1, wherein
the lead frame has a bar lead of square ring shape inside the inner leads; and
in the step (c), the semiconductor chip and the thermoplastic binding material are joined, suppressing the tip parts of the inner leads, and the bar lead to the stage side.

3. A manufacturing method of a semiconductor device according to claim 1, wherein
a glass transition temperature of the thermoplastic binding material is more than or equal to 250° C.

4. A manufacturing method of a semiconductor device assembled using a lead frame which has a plurality of inner leads, a plurality of outer leads formed in one with this, and a sheet member joined to tip parts of the inner leads, comprising the steps of:
(a) preparing the lead frame in which the sheet member, and the tip parts of the inner leads were joined via a binding material, and a first through hole was formed inside the inner lead of the sheet member;
(b) mounting a semiconductor chip over the sheet member of the lead frame;
(c) connecting electrically an electrode of the semiconductor chip, and the inner lead corresponding to this with an electrically conductive wire;
(d) arranging a back surface over which the semiconductor chip is not mounted of the lead frame over a metal-mold surface of a metal mold with which a gate was formed among forming molds which include a pair with a first metal mold and a second metal mold, and clamping the first and the second metal mold after that; and
(e) filling up a resin for sealing in a cavity pushing up the wire arranged at a front surface side by pouring in the resin for sealing into the cavity of the metal mold from the gate, and passing from the back surface side of the lead frame to the first through hole.

5. A manufacturing method of a semiconductor device according to claim 4, wherein
the lead frame has a bar lead of square ring shape inside the inner leads; and
in the step (e), the resin for sealing fills up in the cavity pushing up the wire by passing to the first through hole formed between the inner lead and the bar lead.

6. A manufacturing method of a semiconductor device according to claim 4, wherein
the sheet member is a heat spreader and the first through hole is formed in the heat spreader.

7. A manufacturing method of a semiconductor device assembled using a lead frame which has a plurality of inner leads, a plurality of outer leads formed in one with this, and a sheet member joined to tip parts of the inner leads, comprising the steps of:
(a) preparing the lead frame in which the sheet member, and the tip parts of the inner leads were joined via a binding material, a chip mounting part smaller than a back surface of a semiconductor chip was arranged via the binding material over the sheet member, and a second through hole was formed in a perimeter of the chip mounting part;
(b) mounting the semiconductor chip over the chip mounting part of the sheet member of the lead frame;
(c) connecting electrically an electrode of the semiconductor chip, and the inner lead corresponding to this with an electrically conductive wire;
(d) arranging a back surface over which the semiconductor chip is not mounted of the lead frame over a metal-mold surface of a metal mold with which a gate was formed among forming molds which include a pair with a first metal mold and a second metal mold, and clamping the first and the second metal mold after that; and
(e) filling up a resin for sealing in a cavity by pouring in the resin for sealing into the cavity of the metal mold from the gate, circulating from the back surface side of the lead frame to a front surface side through the second through hole, and supplying to the back surface of the semiconductor chip.

8. A manufacturing method of a semiconductor device according to claim 7, wherein
a first through hole is formed inside the inner lead of the sheet member; and
in the step (e), a resin for sealing fills up in a cavity pushing up the wire arranged at a front surface side by pouring in the resin for sealing into the cavity of the metal mold from the gate, and passing from the back surface side of the lead frame to the first through hole.

9. A manufacturing method of a semiconductor device according to claim 8, wherein
the lead frame has a bar lead of square ring shape inside the inner leads; and
in the step (e), the resin for sealing fills up in the cavity pushing up the wire by passing to the first through hole formed between the inner lead and the bar lead.

10.-12. (canceled)
